(19) United States
(12) Patent Application Publication
(10) Pub. No.: US 2011/0057219 A1
(43) Pub. Date: Mar. 10, 2011

(54) NITRIDE-BASED SEMICONDUCTOR LIGHT EMITTING DEVICE

(75) Inventor: CHIH-CHEN LAI, Tu-Cheng (TW)

(73) Assignee: HON HAI PRECISION INDUSTRY CO., LTD., Tu-Cheng (TW)

(21) Appl. No.: 12/713,177

(22) Filed: Feb. 26, 2010

(30) Foreign Application Priority Data
Sep. 10, 2009 (CN) 200910306842.9

(51) Int. Cl. H01L 33/00

(52) U.S. Cl. 257/98; 257/103; 257/E33.023; 257/E33.067

(57) ABSTRACT

An exemplary nitride-based semiconductor light emitting device includes a substrate, a nitride-based multi-layered structure epitaxially formed on the substrate, a first-type electrode and a second-type electrode formed on the nitride-based multi-layered structure and connected with the first-type layer and the second-type layer, respectively. The multi-layered structure includes a first-type layer, an active layer and a second-type layer arranged along a direction away from the substrate in the order written. The second-type layer defines a number of grooves at the top surface. Each groove has a side surface and a bottom surface adjoining the side surface. The side surface and the bottom surface cooperatively form an included angle which is in a range from 140 degree to 160 degree.

### BACKGROUND

1. Technical Field

The present disclosure generally relates to solid state light emitting devices and, more particularly, to a nitride-based semiconductor light emitting device with high light extraction efficiency.

2. Discussion of Related Art

Nowadays, nitride-based semiconductor light emitting devices such as gallium nitride LEDs (i.e., light emitting diodes) have the advantages of low-power consumption and long life-span, etc, and thus are widely used for display, backlight, outdoor illumination, automobile illumination, etc. However, in order to achieve high luminous brightness, an improvement of light extraction efficiency of the conventional nitride-based LEDs is required.

Kao et al. has published a paper on IEEE photonics technology letters, vol. 19, No. 11, page 849-851 (June, 2007) entitled “light-output enhancement of nano-roughened GaN laser lift-off light-emitting diodes formed by ICP dry etching”, the disclosure of which is fully incorporated herein by reference. Kao et al. has proposed an approach for the improvement of the light extraction efficiency of the GaN LED, by way of forming a number of grooves on a light-emitting region of the GaN LED via an ICP-RIE (i.e., inductively coupled plasma-reactive ion etching) dry etching. However, side-surfaces of the grooves are usually perpendicular to an active layer and can not be used as light emitting surfaces; therefore, it is difficult to improve light extraction efficiency of the GaN LED due to the limitative area of the light emitting surface of the LED.

Therefore, what is needed is a nitride-based semiconductor light emitting device with high light extraction efficiency.

### BRIEF DESCRIPTION OF THE DRAWINGS

FIG. 1 is a top plan view of a nitride-base semiconductor light emitting device, in accordance with an embodiment of the present disclosure.

FIG. 2 is a cross-sectional view of the nitride-base semiconductor light emitting device of FIG. 1, taken along line II-II thereof.

FIG. 3 is a graph of light extraction efficiency vs. angle for the nitride-base semiconductor light emitting device of FIG. 1.

FIG. 4 is a graph of light extraction efficiency vs. current for the nitride-base semiconductor light emitting device of FIG. 1.

### DETAILED DESCRIPTION OF EMBODIMENTS

Reference will now be made to the drawings to describe various embodiments of the present nitride-base semiconductor light emitting device in detail.

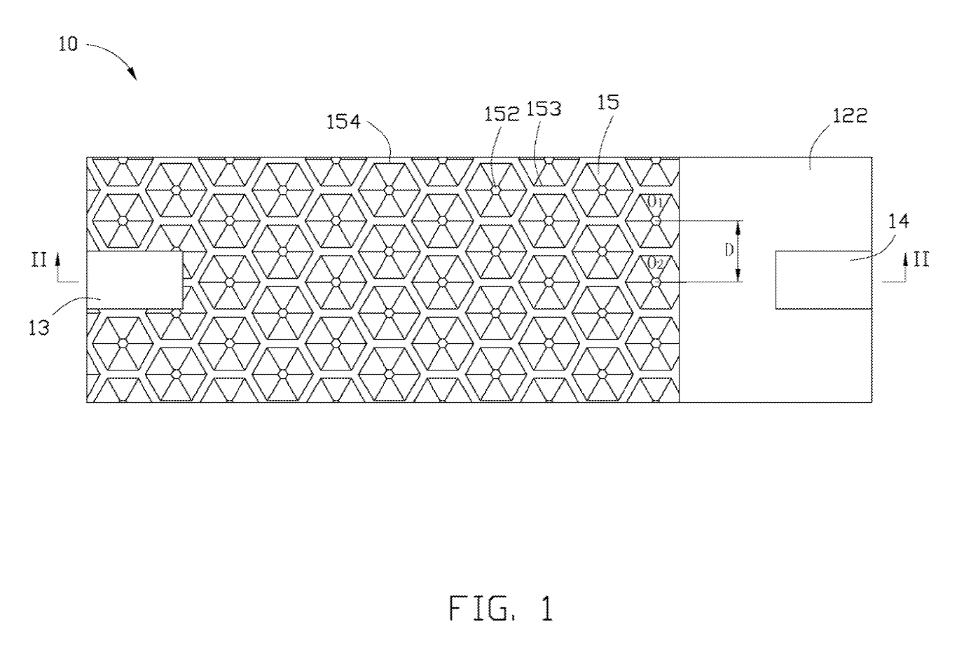

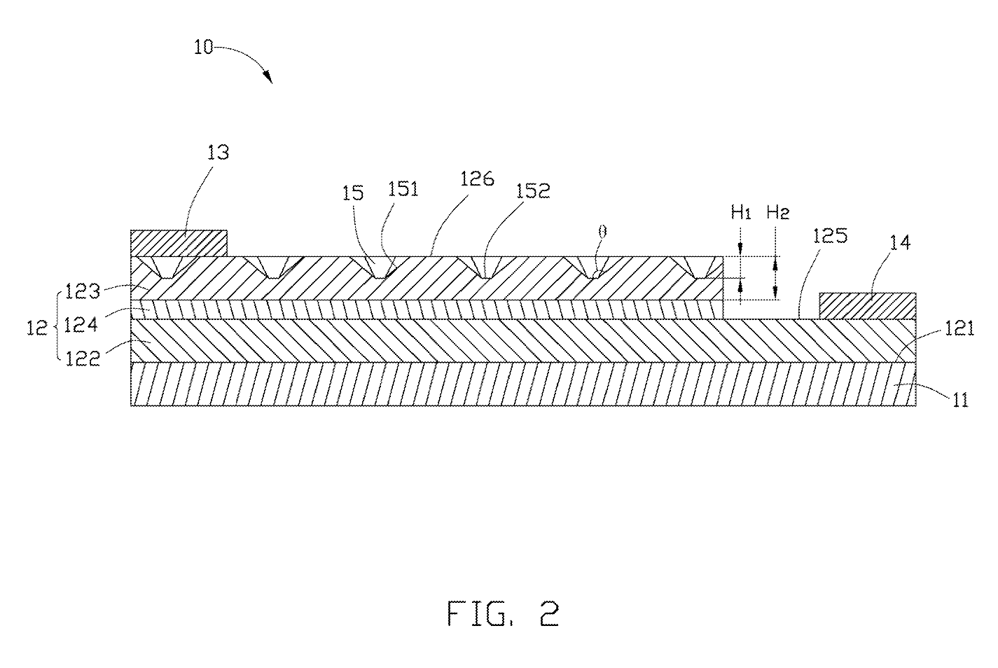

Referring to FIGS. 1-2, a nitride-base semiconductor light emitting device 10, such as a gallium nitride light emitting diode (GaN LED), in accordance with the present embodiment, is provided. The light emitting device 10 includes a substrate 11, a nitride-based multi-layered structure 12 epitaxially formed on the substrate 11, an N-type electrode 14 and a P-type electrode 13 formed on the nitride-based multi-layered structure 12.

The substrate 11 beneficially is a single crystal plate and can be made from a material of sapphire, silicon carbide (SiC), silicon (Si), gallium arsenide (GaAs), lithium aluminate (LiAlO₂), magnesium oxide (MgO), zinc oxide (ZnO), GaN, aluminum nitride (AlN) or indium nitride (InN), etc. The substrate 11 has a crystal face 121 facilitating the epitaxial growth of the nitride-based multi-layered structure 12 thereon. A crystal growth orientation of the crystal face 121 matches with a crystal growth orientation of the multi-layered structure 12.

The multi-layered structure 12 includes an N-type layer 122, an active layer 124 and a P-type layer 123 arranged along a direction away from substrate 11, in the order written. That is, the active layer 124 is sandwiched between the N-type layer 122 and the P-type layer 123. The N-type layer 122 is of an opposite conductive type with respect to the P-type layer 123. The N-type layer 122, the active layer 124 and the P-type layer 123 individually can be a single layer structure or a multi-layered structure, and suitably made from group III-nitride compound materials. The group III element can be aluminum (Al), gallium (Ga), indium (In) and so on. In this embodiment, the N-type layer 122, the active layer 124 and the P-type layer 123 respectively are an N-type GaN layer, an InGaN layer and a P-type GaN layer. The multi-layered structure 12 has a developed mesa structure, whereby the N-type layer 122 is partially exposed to form an exposed portion 125 at a side facing away from the substrate 11. The P-type layer 123 has a top surface 126 facing away from the substrate 11. In one embodiment, the multi-layered structure 12 may include a P-type layer, an active layer and an N-type layer arranged along a direction away from substrate 11.

The P-type layer 123 defines a number of grooves 15 at the top surface 126 thereof. The grooves 15 each have a side surface 151 and a bottom surface 152 adjoining the side surface 151. The side surface 151 and the bottom surface 152 cooperatively form an included angle θ, and the angle θ ranges from 140 degree to 160 degree. The grooves 15 each can have a shape of a conversed truncated-cone, or a conversed truncated-pyramid. In this embodiment, the grooves 15 are arranged on the top surface 126 in an array and spaced from each other. The grooves 15 each have a shape of a conversed truncated-pyramid with six edges 154 on the top surface 126 of the P-type layer 123. The edges 154 of each groove 15 cooperatively define a hexagon, that is, each groove 15 has a hexagonal shape as viewed from a top of the light emitting device 10. Lengths of the edges 154 are equivalent. The length of each edge 154 ranges from 0.5 to 2 micron. The hexagon of each groove 15 has an imaginary center, and a length D between centers, such as O₁, O₂, of two adjacent hexagons ranges from 0.85 to 3.5 micron. In the present embodiment, a height H₁ of the groove 15 is a half of that of the P-type layer 123.

The grooves 15 are defined in the top surface 126 of the P-type layer 123 by ICP-RIE dry etching. An exemplary method for fabricating the grooves 15 will be described in detail: providing a substrate 11; epitaxially growing a nitride-based multi-layered structure 12 on the substrate 11; providing with strong oxidation air, such as chlorine and argon, thereby etching a light-emitting region of the nitride-based multi-layered structure 12 via an ICP-RIE to form a number of the grooves 15 on the P-type layer 123 of the nitride-based multi-layered structure 12. Furthermore, it can adjust the angle θ via changing the concentration of chlorine and argon.

The N-type electrode 14 is formed on the exposed portion 125 of the N-type layer 122 so as to electrically connect (e.g., ohmic contact) with the N-type layer 122. The N-type electrode 14 usually includes at least one metallic layer which is in ohmic contact with the N-type layer 122.

The P-type electrode 13 is formed on the top surface 126 of the P-type layer 123 so as to electrically connect (e.g., ohmic contact) with the P-type layer 123. The P-type electrode 13 can be a single metallic layer or a multi-layered structure consisting of a metallic layer and a transparent conductive film.

The grooves 15 of the P-type layer 123 are configured for eliminating total-reflection to improve the light extraction efficiency of the light emitting device 10.

Furthermore, the angle θ is in a range from 140 degree to 160 degree; therefore, the side surface 151 can be as a light emitting surface, and the light extraction efficiency of the light emitting device 10 is improved due to the increased area of the light emitting surface.

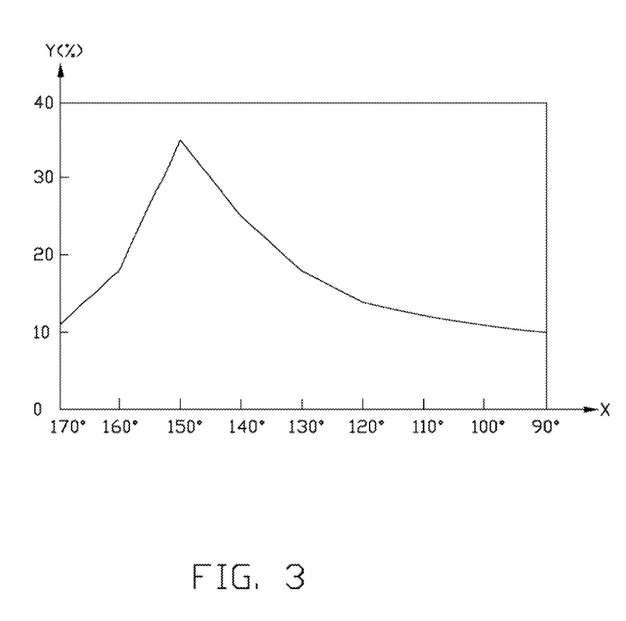

Referring to FIG. 3, a graph of light extraction efficiency of the light emitting device 10 is provided. X-axis represents the angle θ cooperatively formed by the side surface 151 and the bottom surface 152, and Y-axis represents the light extraction efficiency of the light emitting device 10. It can be seen from FIG. 3, when the angle θ is within the range from 140 degree to 160 degree, the light extraction efficiency of the light emitting device 10 has a larger value. When the angle θ is 150 degree, the light extraction efficiency of the light emitting device 10 achieves a peak value.

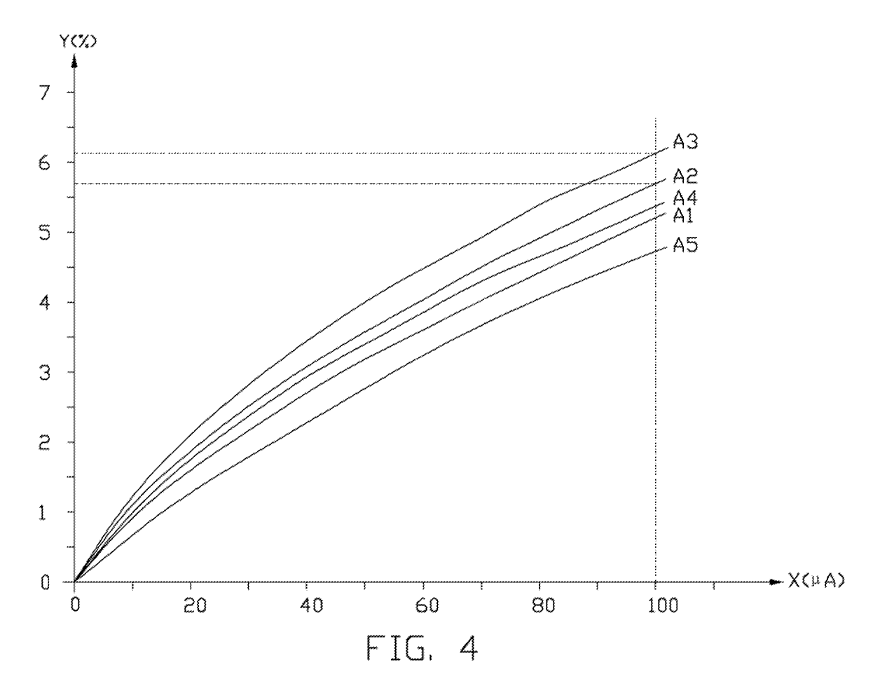

Referring to FIG. 4, a graph of the light extraction efficiency of the light emitting device 10 from another aspect is provided. X-axis represents the current of the light emitting device 10, and Y-axis represents the light extraction efficiency of the light emitting device 10. Curves A1, A2, A3, A4 and A5 respectively indicate the light extraction efficiencies of the light emitting device 10 in condition that the height of the P-type layer 123 is H₂, and the height H₁ of the grooves 15 is zero,

$$\frac{1}{3} {H}_{2} , \frac{1}{2} {H}_{2} , \frac{2}{3} {H}_{2} , and \frac{5}{6} {H}_{2} ,$$

respectively. It can be seen from the FIG. 4, when driven by a current of 100 microampere, the light emitting device 10 has a light extraction efficiency of 62%, in condition that

$${H}_{1} = \frac{1}{2} {H}_{2} ;$$

the light emitting device 10 has a light extraction efficiency of 57%, in condition that

$${H}_{1} = \frac{1}{3} {H}_{2} .$$

Therefore, the light emitting device 10 has a higher light extraction efficiency in condition that the height H₁ of the grooves 15 is in a range from

$$\frac{1}{3} {H}_{2} to \frac{1}{2} {H}_{2} .$$

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. A nitride-based semiconductor light emitting device, comprising:
a substrate;
a nitride-based multi-layered structure epitaxially formed on the substrate, the multi-layered structure including a first-type layer, an active layer and a second-type layer arranged along a direction away from the substrate in the order written, the second-type layer and the active layer cooperatively forming a developed mesa structure, the first-type layer having an exposed portion, the second-type layer having a top surface facing away from the substrate, the second-type layer defining a number of grooves at the top surface thereof, each of the grooves having a side surface and a bottom surface adjoining the side surface, the side surface and the bottom surface cooperatively forming an included angle which is in a range from 140 degree to 160 degree;
a first-type electrode formed on the exposed portion of the first-type layer and brought into ohmic contact with the first-type layer; and
a second-type electrode formed on the top surface of the second-type layer and brought into ohmic contact with the second-type layer.

2. The nitride-based semiconductor light emitting device of claim 1, wherein the substrate is a single crystal plate having a crystal face on which the multi-layered structure is epitaxially formed, the crystal growth orientation matching with the crystal growth orientation of the crystal face.

3. The nitride-based semiconductor light emitting device of claim 2, wherein the single crystal plate is made from a material selected from the group consisting of sapphire, silicon carbide, silicon, gallium arsenide, lithium aluminate, magnesium oxide, zinc oxide, gallium nitride, aluminum nitride and indium nitride.

4. The nitride-based semiconductor light emitting device of claim 1, wherein the first-type layer, the active layer and the second-type layer are made from group III-nitride compound materials.

5. The nitride-based semiconductor light emitting device of claim 1, wherein the first-type layer, the active layer and the second-type layer are a N-type layer, an active layer and a P-type layer, respectively.

6. The nitride-based semiconductor light emitting device of claim 1, wherein each of the grooves has a conversed truncated-conical shape, or a conversed truncated-pyramid shape.

7. The nitride-based semiconductor light emitting device of claim 1, wherein each of the groove has a conversed truncated-pyramid shape with six edges on the top surface of the second-type layer, and lengths of the edges are equivalent to each other.

8. The nitride-based semiconductor light emitting device of claim 7, wherein each of the lengths of the edges of each groove ranges from 0.5 to 2 micron.

9. The nitride-based semiconductor light emitting device of claim 1, wherein the groove is a conversed truncated-pyramid, and the groove has a hexagonal shape on the top surface of the second-type layer, and a length between centers of the adjacent hexagon ranges from 0.85 to 3.5 micron.

10. The nitride-based semiconductor light emitting device of claim 1, wherein the height of the groove is H₁, and the height H₂ of the second-type layer ranges from
$$\frac{1}{3} {H}_{2} to \frac{1}{2} {H}_{2} .$$

11. The nitride-based semiconductor light emitting device of claim 1, wherein the grooves are formed by ICP-RIE dry etching.
